(19) United States
(12) Patent Application Publication
(10) Pub. No.: US 2025/0118700 A1
(43) Pub. Date: Apr. 10, 2025

(54) SEMICONDUCTOR DEVICE AND METHOD OF MANUFACTURING THE SAME

(71) Applicant: QUANZHOU SANAN INTEGRATED CIRCUIT CO.,LTD., Quanzhou (CN)

(72) Inventors: Xiaopeng GUO, Quanzhou (CN); Jianming YU, Quanzhou (CN); Ziyuan WANG, Quanzhou (CN); Junrui LUO, Quanzhou (CN); Lijiao LIU, Quanzhou (CN)

(21) Appl. No.: 18/900,914

(22) Filed: Sep. 30, 2024

(30) Foreign Application Priority Data
Oct. 9, 2023 (CN) 202311300173.0

(51) Int. Cl. H01L 23/00

(52) U.S. Cl. CPC H01L 24/48; H01L 24/85; H01L 2224/48096; H01L 2224/48227; H01L 2224/85181; H01L 2224/85201; H01L 2924/37001

(57) ABSTRACT

A semiconductor device includes: a first wire bonding area with a first bonding pad, a second wire bonding area with a second bonding pad, and a first bonding wire connecting the first bonding pad to the second bonding pad. The first bonding wire includes a lower pressing section and a first line segment connecting the lower bonding part to the first bonding pad. A distance between the lower pressing section and a plane where the second wire bonding area is located is defined as a first height, which is smaller than 400 μm, a length of an orthographic projection of the first bonding wire on the plane is defined as a first length, a length of an orthographic projection of the first line segment on the plane is defined as a second length, and the second length is 20%-80% of the first length.

### CROSS-REFERENCE TO RELATED APPLICATION

This application claims priority to Chinese Patent Application No. 202311300173.0, filed on Oct. 9, 2023, which is herein incorporated by reference in its entirety.

### TECHNICAL FIELD

The disclosure relates to the field of semiconductor wire bonding technologies, and more particularly to a semiconductor device and a method of manufacturing the same.

### BACKGROUND

Wire bonding is an important step in a semiconductor packaging process. In the wire bonding process, a bonding wire is bonded to a corresponding bonding pad by controlling movement of a wire bonding tool such as a capillary to achieve electrical connection between different bonding pads. With a rapid development of technology, semiconductor products are moving towards miniaturization, thus spacing between the bonding wires on the semiconductor packaging products are getting smaller and smaller. For the existing wire bonding structure, when the spacing between the bonding wires is small, the wire bonding tool or the bonding wires formed later can cause collision, squeeze or bend to the previously bonded bonding wires. Severe bending will cause the squeezed bonding wire to touch other bonding wires, causing short circuit after the wire collision, and more seriously, it will cause the product to be scrapped.

Therefore, it is urgent to provide a semiconductor device to solve the problem of easy wire collision in the existing wire bonding structure.

### SUMMARY

Embodiments of the disclosure provide a semiconductor device and a method of manufacturing the same, which can avoid occurrence of a wire collision problem, and improve product quality and yield.

An embodiment of the disclosure provides a semiconductor device, including: at least one carrier, a first wire bonding area, a second wire bonding area and at least one bonding wire. The first wire bonding area and the second wire bonding area are disposed on the at least one carrier. A first bonding pad is disposed on the first wire bonding area. A second bonding pad is disposed on the second wire bonding area. The at least one bonding wire includes a first bonding wire connecting the first bonding pad to the second bonding pad. The first bonding wire includes a lower pressing section and a first line segment, and the first line segment connects the lower pressing section to the first bonding pad. A distance between the lower pressing section and a plane where the second wire bonding area is located is defined as a first height, and the first height is smaller than 400 microns (μm). A length of an orthographic projection of the first bonding wire on the plane where the second wire bonding area is located is defined as a first length, while a length of an orthographic projection of the first line segment on the plane where the second wire bonding area is defined as a second length, and the second length is 20% to 80% of the first length.

An embodiment of the disclosure provides a method of manufacturing the semiconductor device, and the method of manufacturing the semiconductor device is applied to a to-be-bonded structure (e.g., the semiconductor device). The to-be-bonded structure includes: a first wire bonding area and a second wire bonding area. A first bonding pad is disposed on the first wire bonding area. A second bonding pad is disposed on the second wire bonding area. A length of an orthographic projection of a line connecting the first bonding pad to the second bonding pad on a plane where the second wire bonding area is located is defined as a first length.

The method of manufacturing the semiconductor device includes: providing at least one carrier that includes a first wire bonding area and a second wire bonding area, disposing a first bonding pad on the first wire bonding area, disposing a second bonding pad on the second wire bonding area, forming a first bonding wire between the first bonding pad and the second bonding pad, and creating a lower pressing section on the first bonding wire. A distance between the lower pressing section and the plane where the second wire bonding area is located is defined as a first height, and the first height is smaller than 400 μm. A length of an orthographic projection of a line connecting the lower pressing section to the first bonding pad on the plane where the second wire bonding area is located is defined as a second length, and the second length is 20% to 80% of the first length.

The above embodiments of the disclosure have at least one of the following beneficial effects. In the semiconductor device and the preparation method thereof provided by the embodiments of the disclosure, the lower pressing section is formed on the first bonding wire, and the height and a position of the lower pressing section are controlled, so that a position of the first bonding wire at the lower pressing section is low, the first bonding wire is not easily squeezed or collided by other bonding wires to cause the occurrence of the wire collision problem in the subsequent process of bonding other bonding wires. Therefore, it can reduce the risk of short circuit caused by wire collision and improve product yield.

### BRIEF DESCRIPTION OF DRAWINGS

Embodiments of the disclosure will be described in details below in conjunction with drawings.

FIG. 1 illustrates a schematic structural diagram from a front-rear perspective of a semiconductor device according to an embodiment of the disclosure.

FIG. 2 illustrates a schematic structural diagram from a front-rear perspective of a semiconductor device according to an embodiment of the disclosure.

FIG. 3 illustrates a schematic structural diagram from a top-down perspective of the semiconductor device in FIG. 2.

FIG. 4 illustrates a schematic structural diagram from a front-rear perspective of a semiconductor device according to an embodiment of the disclosure.

FIG. 5 illustrates a schematic structural diagram from a top-down perspective of the semiconductor device in FIG. 4.

FIG. 6 illustrates a schematic structural diagram from a top-down perspective of a semiconductor device according to an embodiment of the disclosure.

FIG. 7 illustrates a schematic structural diagram from a front-rear perspective of the semiconductor device in FIG. 6.

FIG. 8 illustrates a schematic structural diagram from a top-down perspective of a specific embodiment of the semiconductor device in FIG. 6.

FIG. 9 illustrates a schematic structural diagram from a front-rear perspective of the semiconductor device in FIG. 8.

FIG. 10 illustrates a principle diagram of a semiconductor device according to an embodiment of the disclosure.

FIG. 11 illustrates a schematic structural diagram from a top-down perspective of a semiconductor device according to an embodiment of the disclosure.

FIG. 12 illustrates a schematic structural diagram from a top-down perspective of a semiconductor device according to an embodiment of the disclosure.

FIG. 13 illustrates a schematic structural diagram from a top-down perspective of a semiconductor device according to an embodiment of the disclosure.

FIG. 14 illustrates a schematic structural diagram from a top-down perspective of a semiconductor device according to an embodiment of the disclosure.

FIG. 15 a schematic structural diagram from a top-down perspective of a specific embodiment of the semiconductor device in FIG. 14.

FIG. 16 illustrates a schematic structural diagram from a front-rear perspective of the semiconductor device in FIG. 15.

### DETAILED DESCRIPTION OF EMBODIMENTS

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

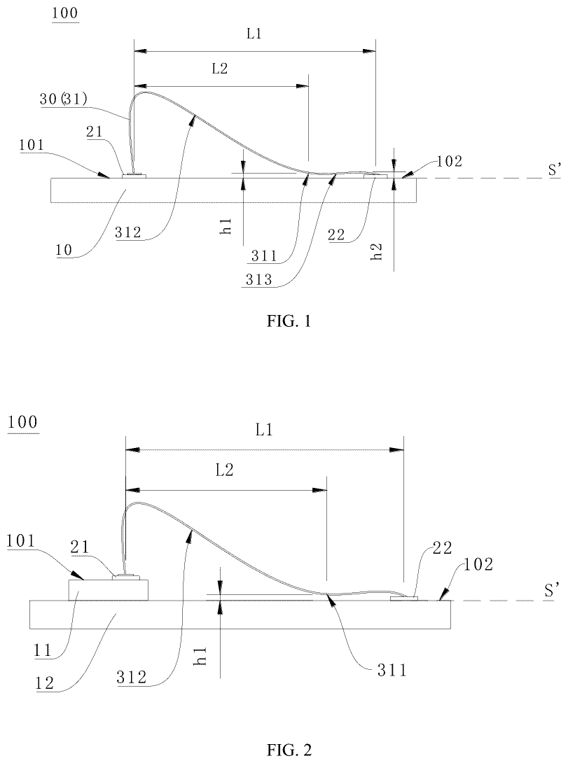

An embodiment of the disclosure provides a semiconductor device 100, as shown in FIG. 1. The semiconductor device 100 includes a first wire bonding area 101, a second wire bonding area 102 and at least one bonding wire 30. A first bonding pad 21 is disposed on the first wire bonding area 101. A second bonding pad 22 is disposed on the second wire bonding area 102. The at least one bonding wire 30 includes a first bonding wire 31 which connects the first bonding pad 21 to the second bonding pad 22. The first bonding wire 31 includes a lower pressing section 311 and a first line segment 312, and the first line segment 312 connects the lower pressing section 311 to the first bonding pad 22. A distance between the lower pressing section 311 and a plane S′ where the second wire bonding area 102 is located is defined as a first height h1, and the first height h1 is smaller than 400 μm. An orthographic projection of the first bonding wire 31 on the plane S′ where the second wire bonding area 102 is located has a first length L1, an orthographic projection of the first line segment 312 on the plane S′ where the second wire bonding area 102 is located has a second length L2, and the second length L2 is 20% to 80% of the first length L1. In some embodiments, the second length L2 can be 30% to 70% of the first length L1. For example, the second length L2 can be 20%, 25%, 31%, 40%, 50%, 55%, 63%, 68%, 70%, 77% or 80% of the first length L1.

Specifically, the semiconductor device 100 includes a carrier 10 which can be a chip or a substrate. As shown in FIG. 1, each of the first wire bonding area 101 and the second wire bonding area 102 can be disposed on a surface of the carrier 10, that is, the first wire bonding area 101 and the second wire bonding area 102 are located on different areas of the carrier 10.

In some embodiments, the semiconductor device 100 includes a first carrier 11 and a second carrier 12. The first wire bonding area 101 is located on the first carrier 11, and the second wire bonding area 102 is located on the second carrier 12. The first carrier 11 can be a chip or a substrate, and the second carrier 12 can be a chip or a substrate. Specifically, the semiconductor device 100 can may be a chip having the first bonding wire 31, the first bonding pad 21 and the second bonding pad 22, a substrate having the first bonding wire 31, the first bonding pad 21 and the second bonding pad 22, a combination of two chips connected through the first bonding wire 31, a combination of two substrates connected through the first bonding wire 31, or a combination of a chip and a substrate connected through the first bonding wire 31. The embodiment is not limited to the above embodiments. As shown in FIG. 2, the first carrier 11 is a chip, the second carrier 12 is a substrate, the first carrier 11 is disposed on the second carrier 12, and the first carrier 11 is electrically connected to the second carrier 12 through the first bonding wire 31.

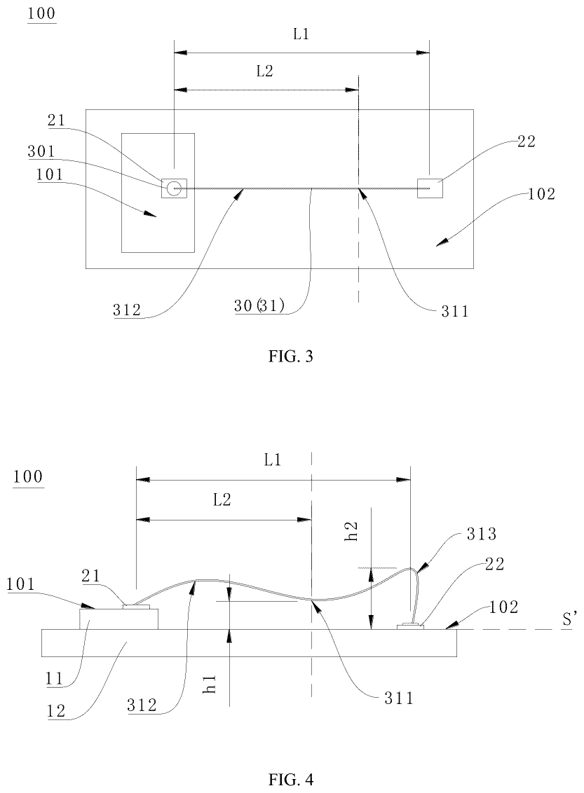

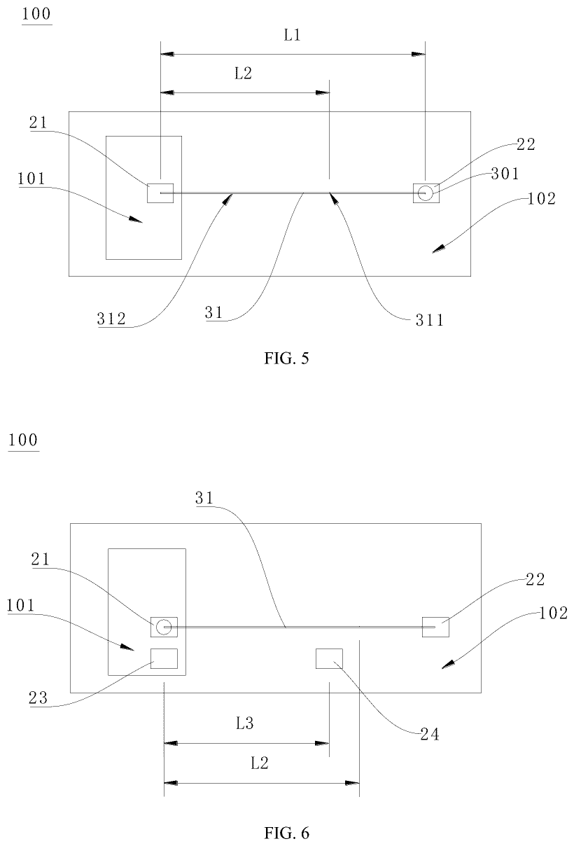

Continuing the above, the first bonding wire 31 can be a gold wire, a copper wire or an alloy bonding wire. The copper wire can be a pure copper wire, a palladium copper wire or a gold palladium copper wire. A diameter d of the bonding wire 30 (i.e., the first bonding wire 31) is in a range of 15 μm to 60 μm. For example, the diameter d can be 18 μm, 20 μm, 25 μm, 30 μm, 38 μm or 50 μm. Specifically, as shown in FIG. 2 and FIG. 3, the first bonding wire 31 can be a “forward bonding” structure from the first bonding pad 21 to the second bonding pad 22, and a bonding ball 301 is formed on the first bonding pad 21. Alternatively, as shown in FIG. 4 and FIG. 5, the first bonding wire 31 can be a “reverse bonding” structure from the second bonding pad 22 to the first bonding pad 21, and the bonding ball 301 is formed on the second bonding pad 22. Specifically, the “forward bonding” and the “reverse bonding” are in a relative relationship, and directions of the “forward bonding” and the “reverse bonding” are opposite to each other.

In the embodiments of the disclosure, the lower pressing section 311 is formed on the first bonding wire 31, so that a position of the first bonding wire 31 near the lower pressing section 311 is relatively low. As shown in FIG. 1 and FIG. 4, a concavity is formed near the lower pressing section 311. Specifically, as shown in FIG. 1 and FIG. 4, the first bonding wire 31 further includes a second line segment 313 connected between the lower pressing section 311 and the second bonding pad 22, a highest distance between the second line segment 313 and the plane S′ where the second wire bonding area 102 is located is defined as a second height h2, the second height h2 is greater than the first height h1, that is, at least one point on the second line segment 313 is higher than the lower pressing section 311. Therefore, during the wire bonding of the semiconductor device 100, when forming other bonding wires after forming the first bonding wire 31, a wire bonding tool or the other bonding wires formed after the first bonding wire 31 are less likely to squeeze the first bonding wire 31 when passing near the lower pressing section 311, which can prevent short circuit and improve product yield.

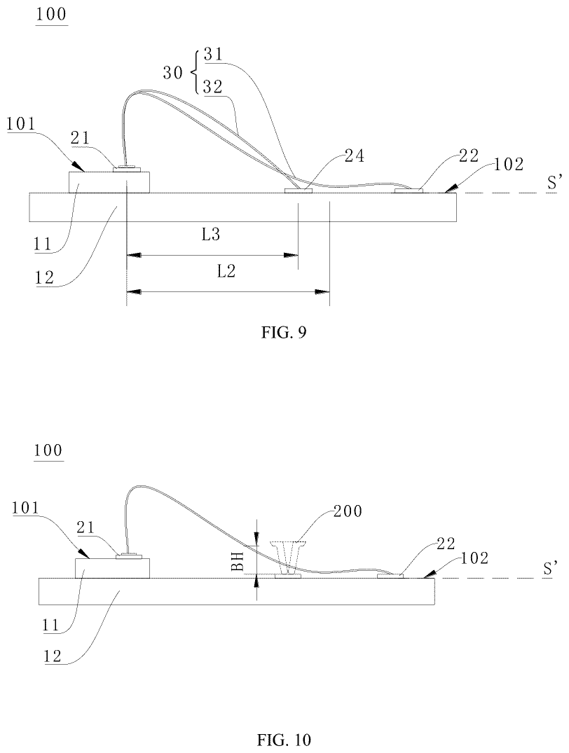

In some embodiments, as shown in FIG. 6, a third bonding pad 23 is disposed on the first wire bonding area 101, and the third bonding pad 23 is adjacent to the first bonding pad 21. A fourth bonding pad 24 is disposed on the second wire bonding area 102, the fourth bonding pad 24 is opposite to the third bonding pad 23, and the fourth bonding pad 24 is located on a side of the second bonding pad 22 proximate to the first bonding pad 21. The third bonding pad 23 is connected to the fourth bonding pad 24 by a second bonding wire 32 (as shown in FIG. 9). During a packaging process of the semiconductor device 100, the second bonding wire 32 is formed between the third bonding pad 23 and the fourth bonding pad 24 after forming the first bonding wire 31. During forming the second bonding wire 32, as shown in FIG. 10, a wire bonding tool such as a capillary 200 descends onto the fourth bonding pad 24 during connecting the second bonding wire 32 and the fourth bonding pad 24. Due to difficulty in further reducing a diameter of the capillary 200, and the inability to increase a bottleneck height (BH, the BH can also be referred to as a height of a tip of the capillary 200, the diameter at the tip is smaller, while the diameter above the tip is larger) of the capillary 200 without limit, when the first bonding wire 31 adopts a traditional bonding wire structure, the capillary 200 squeezes the first bonding wire 31 to cause the occurrence of a wire collision problem. Therefore, through the semiconductor device 100 provided by the embodiments of the disclosure, due to presence of the lower pressing section 311, a relatively low position is formed on the first bonding wire 31, to thereby avoid the capillary 200 squeezing the first bonding wire 31 during forming the second bonding wire 32. Specifically, the BH of commonly used capillaries 200 includes 150 μm, 200 μm, 250 μm and 300 μm. A shape of the first bonding wire 31 corresponding to the BH of 150 μm can be specifically set to make the first height h1 smaller than 150 μm. A shape of the first bonding wire 31 corresponding to the BH of 200 μm can be specifically set to make the first height h1 smaller than 200 μm. A shape of the first bonding wire 31 corresponding to the BH of 250 μm can be specifically set to make the first height h1 smaller than 250 μm. A shape of the first bonding wire 31 corresponding to the BH of 300 μm can be specifically set to make the first height h1 smaller than 300 μm.

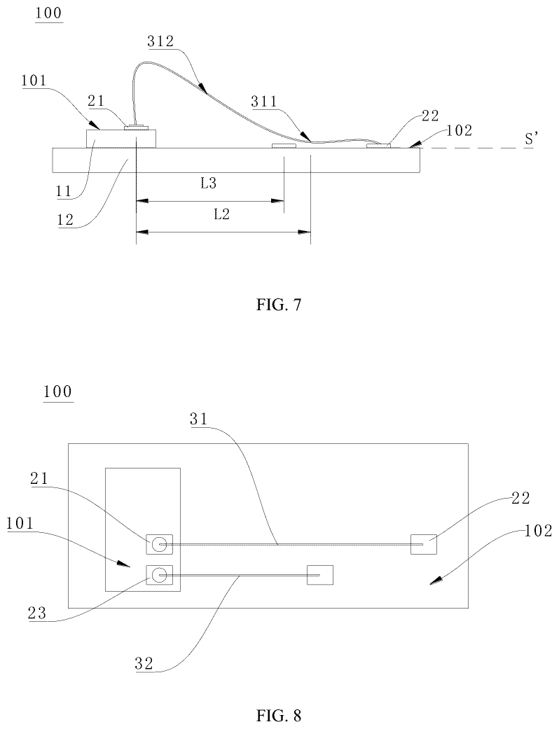

Furthermore, as shown in FIG. 6 and FIG. 7, a length of an orthographic projection of a line connecting the fourth bonding pad 24 to the third bonding pad 23 on the plane S′ where the second wire bonding area is located is defined as a third length L3, and a difference between the second length L2 and the third length L3 is in a range of −200 μm to 200 μm. In an embodiment, the difference between the second length L2 and the third length L3 can be in a range of −100 μm to 100 μm. According to FIG. 6, when the lower pressing section 311 is located on a right side of the fourth bonding pad 24, the second length L2 is greater than the third length L3, and the difference between the second length L2 and the third length L3 is positive, for example, the difference can be 10 μm, 23 μm, 28 μm, 35 μm, 40 μm, 56 μm, 78 μm, 80 μm, 100 μm, 120 μm or 150 μm. According to FIG. 6, when the lower pressing section 311 is located on a left side of the fourth bonding pad 24, the second length L2 is smaller than the third length L3, and the difference between the second length L2 and the third length L3 is negative, for example, the difference can be −1 μm, −5 μm, −10 μm, −21 μm, −25 μm, −30 μm, −40 μm, −50 μm, −75 μm, −90 μm, −100 μm, −130 μm or −140 μm. When the difference between the second length L2 and the third length L3 is 0, it can be considered that the position of the lower pressing section 311 is aligned with the position of the fourth bonding pad 24, which can avoid the capillary 200 better. For example, as shown in FIG. 6, the first bonding wire 31 extends along a horizontal direction shown in FIG. 6, and the third bonding pad 23 and the fourth bonding pad 24 are arranged along the horizontal direction shown in FIG. 6. That is, the two groups of bonding pads (the first bonding pad 21 and the second bonding pad 22 are one group of bonding pads, and the third bonding pad 23 and the fourth bonding pad 24 are the other group of bonding pads) are arranged in parallel. The second length L2 is a distance (also referred as a horizontal distance) between the lower pressing section 311 and the first bonding pad 21 in the schematic structural diagram from the top-down perspective. The third length L3 is a distance (also referred as the horizontal distance) between the fourth bonding pad 24 and the third bonding pad 23 in the schematic structural diagram from the top-down perspective. The difference between the second length L2 and the third length L3 is in a range of −200 μm to 200 μm, which can be understood that the lower pressing section 311 is located within a range of 200 μm in front and behind an alignment position with the fourth bonding pad 24. That is, the lower pressing section 311 is disposed proximate to the fourth bonding pad 24, to thereby avoid the capillary 200 better, and prevent the wire collision.

As shown in FIG. 8 and FIG. 9, the at least one bonding wire 30 further includes a second bonding wire 32, and the second bonding wire 32 connects the third bonding pad 23 to the fourth bonding pad 24. It can be seen from FIG. 9 that in the position corresponding to the fourth bonding pad 24, the first bonding wire 31 is in a lower state, when the capillary 200 bonds the second bonding wire 32 with the fourth bonding pad 24, the first bonding wire 31 can avoid the capillary 200 (as shown in FIG. 10), to prevent wire collision. A diameter of the material of the second bonding wire 32 is the same as the diameter of the material of the first bonding wire 31, and the first bonding wire 31 and the second bonding wire 32 can be gold wires, copper wires or alloy bonding wires. The copper wires can be pure copper wires, palladium copper wires or gold palladium copper wires. The diameter d of the second bonding wire 32 can be 18 μm, 20 μm, 25 μm, 30 μm, 38 μm or 50 μm. Specifically, the second bonding wire 32 can be a “forward bonding” structure from the third bonding pad 23 to the fourth bonding pad 24, and a bonding ball is formed on the third bonding pad 23. Alternatively, the second bonding wire 32 can be a “reverse bonding” structure from the fourth bonding pad 24 to the third bonding pad 23, and the bonding ball is formed on the fourth bonding pad 24.

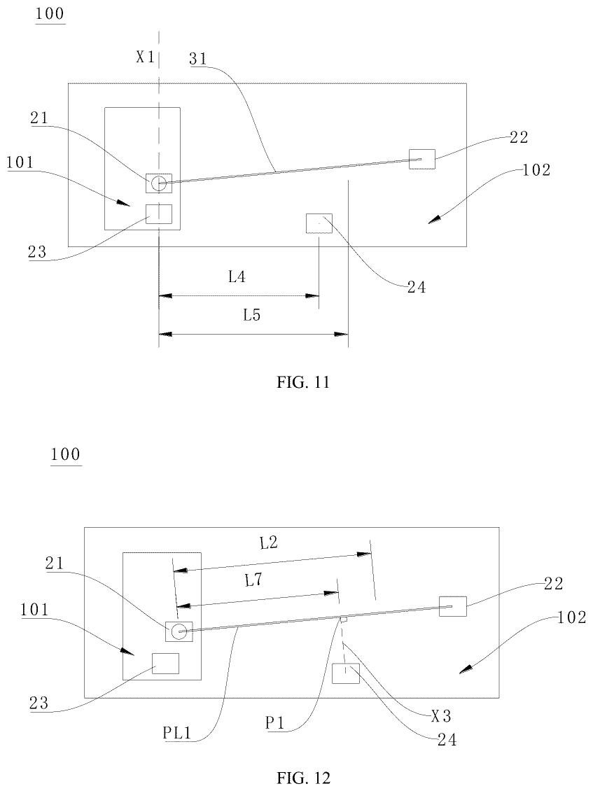

In some embodiments, the two groups of bonding pads (the first bonding pad 21 and the second bonding pad 22 are one group of bonding pads, and the third bonding pad 23 and the fourth bonding pad 24 are the other group of bonding pads) are arranged obliquely. As shown in FIG. 11, a line connecting the first bonding pad 21 to the third bonding pad 23 is defined as a first reference line X1. A length of an orthographic projection of a shortest line connecting the fourth bonding pad 24 to the first reference line X1 on the plane S′ where the second wire bonding area 102 is located is defined as a fourth length L4. A length of an orthographic projection of a shortest line connecting the lower pressing section 311 to the first reference line X1 on the plane S′ where the second wire bonding area 102 is located is defined as a fifth length L5. A difference between the fifth length L5 and the fourth length L4 is in a range of −200 μm to 200 μm. Specifically, the difference between the fifth length L5 and the fourth length L4 is in a range of −100 μm to 100 μm. According to FIG. 11, when the lower pressing section 311 is located on a right side of the fourth bonding pad 24, the fifth length L5 is greater than the fourth length L4, and the difference between the fifth length L5 and the fourth length L4 is positive, for example, the difference can be 8 μm, 20 μm, 25 μm, 31 μm, 44 μm, 54 μm, 70 μm, 85 μm, 100 μm, 130 μm or 148 μm. According to FIG. 11, when the lower pressing section 311 is located on a left side of the fourth bonding pad 24, the fifth length L5 is smaller than the fourth length L4, and the difference between the fifth length L5 and the fourth length L4 is negative, for example, the difference can be −1 μm, −3 μm, −11 μm, −20 μm, −27 μm, −35 μm, −41 μm, −50 μm, −65 μm, −80 μm, −100 μm, −130 μm or −144 μm. When the difference between the fifth length L5 and the fourth length L4 is 0, it can be considered that the position of the lower pressing section 311 is aligned with the position of the fourth bonding pad 24, which can avoid the capillary 200 better. According to FIG. 11, the fourth length L4 is a horizontal distance between the fourth bonding pad 24 and the third bonding pad 23 in the schematic structural diagram from the top-down perspective. The fifth length L5 is a horizontal distance between the lower pressing section 311 and the first bonding pad 21 in the schematic structural diagram from the top-down perspective. It can be understood that the lower pressing section 311 is located within a range of 200 μm in front and behind the alignment position with the fourth bonding pad 24. That is, the lower pressing section 311 is disposed proximate to the fourth bonding pad 24, to thereby avoid the capillary 200 better, and prevent the wire collision.

In some embodiments, as shown in FIG. 12, an orthographic projection of the first bonding wire 31 on the plane S′ where the second wire bonding area 102 is located is defined as a first projection line PL1. A perpendicular line X3 from the fourth bonding pad 24 to the first projection line PL1 intersects with the first projection line PL1 at a first foot of perpendicular (also referred to as foot point) P1. A length of an orthographic projection of a line connecting the first foot of perpendicular P1 to the first bonding pad 21 on the plane S′ where the second wire bonding area 102 is located is defined as a perpendicular distance (also referred to as foot point distance) L7. A difference between the second length L2 and the perpendicular distance L7 is in a range of −100 μm to 100 μm. For example, according to FIG. 12, when the lower pressing section 311 is located on a right side of the first foot of perpendicular P1, the difference between the second length L2 and the perpendicular distance L7 is positive, for example, the difference between the second length L2 and the perpendicular distance L7 can be 5 μm, 11 μm, 23 μm, 30 μm, 45 μm, 50 μm, 60 μm, 75 μm or 100 μm. When the lower pressing section 311 is located on a left side of the first foot of perpendicular P1, the difference between the second length L2 and the perpendicular distance L7 is negative, for example, the difference between the second length L2 and the perpendicular distance L7 can be −2 μm, −8 μm, −15 μm, −26 μm, −30 μm, −40 μm, −63 μm, −65 μm or −100 μm. When the difference between the second length L2 and the perpendicular distance L7 is 0, it can be considered that the position of the lower pressing section 311 is aligned with the position of the fourth bonding pad 24, which can avoid the capillary 200 better.

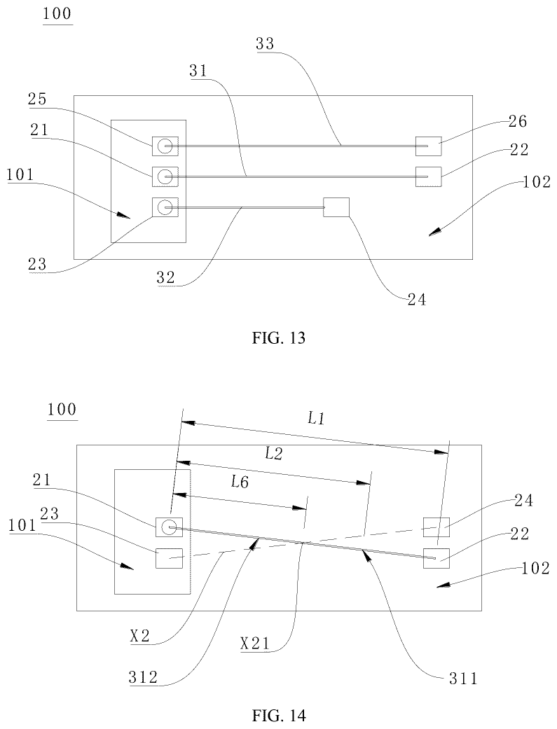

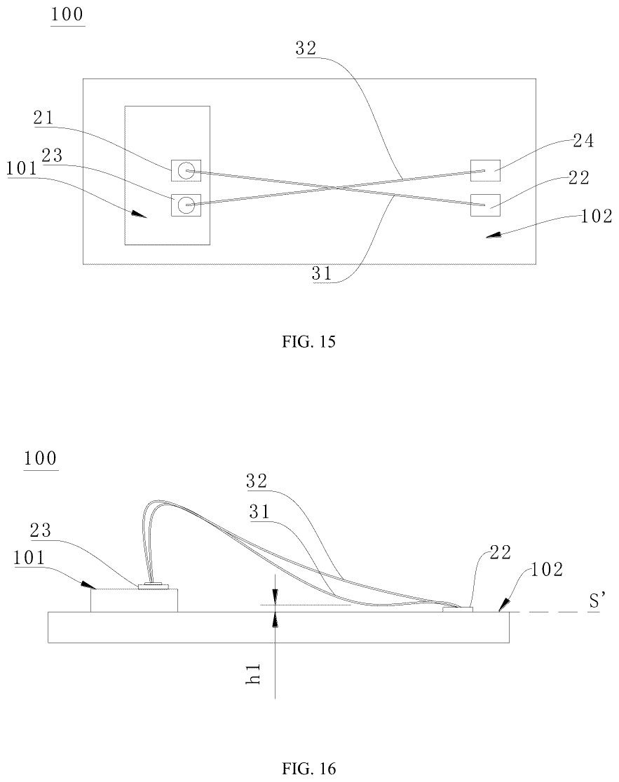

As shown in FIG. 13, the semiconductor device 100 is provided with a third bonding wire 33, and the third bonding wire 33 connects a fifth bonding pad 25 to a sixth bonding pad 26. For example, the third bonding wire 33 and the first bonding wire 31 are formed before forming the second bonding wire 32, during the formation process of the second bonding wire 32, when the capillary 200 squeezes the first bonding wire 21 at the fourth bonding pad 24 to cause the first bonding wire 31 to bend, thus the first bonding wire 31 may collide the third bonding wire 33. In the embodiment, the first bonding wire 31 is provided with the lower pressing section 311, which can avoid the collision of the capillary 200, to thereby prevent the wire collision with the third bonding wire 33.

In an embodiment, a third bonding pad 23 is further disposed on the first wire bonding area 101, and the third bonding pad 23 is adjacent to the first bonding pad 21. A fourth bonding pad 24 is further disposed on the second wire bonding area 102, and the fourth bonding pad 24 is opposite to the third bonding pad 23. The third bonding pad 23 is connected to the fourth bonding pad 24 by the second bonding wire 32. An orthographic projection of the first bonding wire 31 on the plane S′ where the second wire bonding area 102 is located intersects with an orthographic projection of a line connecting the third bonding pad 23 to the fourth bonding pad 24 on the plane S′ where the second wire bonding area 102 is located on an intersection X21. That is, when the second bonding wire 32 needs to be formed after forming the first bonding wire 31, intersecting wire bonding is required. As shown in FIG. 14, a line connecting the third bonding pad 23 to the fourth bonding pad 24 is defined as a second reference line X2, and an orthographic projection of the second reference line X2 on the plane S′ where the second wire bonding area 102 is located intersects with the orthographic projection of the first bonding wire 31 on the plane S′ where the second wire bonding area 102 is located on the intersection X21. Due to the requirement of the intersecting wire bonding, the first bonding wire 31 is provided with the lower pressing section 311, to make the first bonding wire 31 in a lower position near the lower pressing section 311. During forming the second bonding wire 32, when the capillary 200 or the second bonding wire 32 passes over the first bonding wire 31, it is not easy to collide with the first bonding wire 31 after forming the second bonding wire 32.

Specifically, as shown in FIG. 14, a length of an orthographic projection of a line connecting the intersection X21 to the first bonding pad 21 on the plane S′ where the second wire bonding area 102 is located is defined as a sixth length L6. A difference between the second length L2 and the sixth length L6 is in a range of −200 μm to 200 μm. Specifically, the difference between the second length L2 and the sixth length L6 is in a range of −100 μm to 100 μm. It can be understood that the lower pressing section 311 is located within a range of 100 μm before and after the intersection X21 on the first bonding wire 31, which can control the first bonding wire 31 to form a low position on a corresponding area of the intersection X21, to thereby prevent the occurrence of the wire collision. Specifically, according to FIG. 14, when the lower pressing section 311 is located on a right side of the intersection X21, the difference between the second length L2 and the sixth length L6 is positive, for example, the difference can be 2 μm, 15 μm, 20 μm, 33 μm, 43 μm, 55 μm, 67 μm, 79 μm or 100 μm. When the lower pressing section 311 is located on a left side of the intersection X21, the difference between the second length L2 and the sixth length L6 is negative, for example, the difference can be −1 μm, −6 μm, −12 μm, −34 μm, −40 μm, −55 μm, −68 μm, −92 μm or −100 μm. When the difference between the second length L2 and the sixth length L6 is 0, it can be considered that the lower pressing section 311 is aligned with the intersection X21, which can avoid the capillary 200 and the bonding wires better during forming the second bonding wire 32.

In some embodiments, the at least one bonding wire 30 further includes a second bonding wire 32, the second bonding wire 32 connects the third bonding pad 23 to the fourth bonding pad 24, and a minimum distance between the first bonding wire 31 and the second bonding wire 32 is greater than or equal to one time of a diameter of the bonding wire 30. The diameter of the bonding wire 30 can be in a range of 15 μm to 60 μm. When the diameter of the bonding wire 30 is 18 μm, the minimum distance between the first bonding wire 31 and the second bonding wire 32 is greater than or equal to 18 μm. When the diameter of the bonding wire 30 is 20 μm, the minimum distance between the first bonding wire 31 and the second bonding wire 32 is greater than or equal to 20 μm. When the diameter of the bonding wire 30 is 50 μm, the minimum distance between the first bonding wire 31 and the second bonding wire 32 is greater than or equal to 50 μm. In this way, it can prevent the problem that the second bonding wire 32 sinks to collide with the first bonding wire 31 during a sealing process after the wire bonding process.

In some embodiments, the first height h1 is greater than or equal to one time of the diameter of the bonding wire 30. As the aforementioned embodiments, the diameter of the bonding wire 30 is in a range of 15 μm to 60 μm. When the diameter of the bonding wire 30 is 18 μm, the first height h1 is greater than or equal to 18 μm. When the diameter of the bonding wire 30 is 20 μm, the first height h1 is greater than or equal to 20 μm. When the diameter of the bonding wire 30 is 50 μm, the first height h1 is greater than or equal to 50 μm. In this way, it can prevent the problem of contact short circuit with other wires on the second wire bonding area 102 caused by the sinking of the first bonding wire 32 to contact with the second wire bonding area 102 during the sealing process after the wire bonding process.

The embodiments of the disclosure further provide a method of manufacturing the semiconductor device, and the method of manufacturing the semiconductor device is applied to a to-be-bonded structure (e.g., the semiconductor device). The to-be-bonded structure includes: a first wire bonding area 101 and a second wire bonding area 102. A first bonding pad 21 is disposed on the first wire bonding area 101, and a second bonding pad 22 is disposed on the second wire bonding area 102. A length of an orthographic projection of a line connecting the first bonding pad 21 to the second bonding pad 22 on a plane S′ where the second wire bonding area 102 is located is defined as a first length L1.

In some embodiments, the method of manufacturing the semiconductor device includes the following steps: at least one carrier is provided that includes the first wire bonding area 101 and the second wire bonding area 102, a first bonding wire 31 is formed between the first bonding pad 21 and the second bonding pad 22, and a lower pressing section 311 is created on the first bonding wire 31. Specifically, a distance between the lower pressing section 311 and the plane S′ where the second wire bonding area 102 is located is defined as a first height h1, and the first height h1 is smaller than 400 μm. A length of an orthographic projection of a line connecting the lower pressing section 311 to the first bonding pad 21 on the plane S′ where the second wire bonding area 102 is located is a second length L2, and the second length L2 is 20% to 80% of the first length L1. Specifically, the second length L2 is 30% to 70% of the first length L1. For example, the second length L2 can be 20%, 25%, 31%, 40%, 50%, 55%, 63%, 68%, 70%, 77% or 80% of the first length L1.

In some embodiments, the method of manufacturing the semiconductor device specifically includes the following steps: a bonding wire is driven to move between the first bonding pad 21 and the second bonding pad 22 by using a wire bonding tool, to thereby form the first bonding wire 31. When the wire bonding tool moves to a preset position, the wire bonding tool is pressed facing towards a direction proximate to the second wire bonding area 102, to creat the lower pressing section 311 on the first bonding wire 31. The first height h1 is a distance between the wire bonding tool at the preset position and the plane S′ where the second wire bonding area 102 is located.

Specifically, a length (i.e., the second length L2) of a projection of a line connecting the wire bonding tool at the preset position to the first bonding pad 21 on the plane S′ where the second wire bonding area 102 is located is the length of the projection of the line connecting the lower pressing section 311 to the first bonding pad 21 on the plane S′ where the second wire bonding area 102 is located. The first bonding wire 31 includes a first line segment 312 connecting the lower pressing section 311 to the first bonding pad 21. The second length L2 is a length of a projection of the first line segment 312 on the plane S′ where the second wire bonding area 102 is located.

In some embodiments, the distance between the lower pressing section 311 and the plane S′ where the second wire bonding area 102 is located is smaller than a height of a tip of the capillary 200 (i.e., the wire bonding tool).

Specifically, the height of the tip of the wire bonding tool is a BH of the capillary 200, the BH of commonly used capillaries 200 includes 150 μm, 200 μm, 250 μm and 300 μm. Therefore, when the BH of the capillary 200 is 150 μm, the capillary 200 is pressed at the preset position to make a height between the lower pressing section 311 formed on the first bonding wire 31 and the plane S′ where the second wire bonding area 102 is located smaller than 150 μm. When the BH of the capillary 200 is 200 μm, the capillary 200 is pressed at the preset position to make the height between the lower pressing section 311 formed on the first bonding wire 31 and the plane S′ where the second wire bonding area 102 is located smaller than 200 μm. When the BH of the capillary 200 is 250 μm, the capillary 200 is pressed at the preset position to make the height between the lower pressing section 311 formed on the first bonding wire 31 and the plane S′ where the second wire bonding area 102 is located smaller than 250 μm. When the BH of the capillary 200 is 350 μm, the capillary 200 is pressed at the preset position to make the height between the lower pressing section 311 formed on the first bonding wire 31 and the plane S′ where the second wire bonding area 102 is located smaller than 350 μm.

The capillary 200 is pressed at the preset position to form the lower pressing section 311, so that a position of the first bonding wire 31 near the lower pressing section 311 is low. Thus, when other bonding wires are formed after forming the first bonding wire 31 during the wire bonding process of the semiconductor device 100, the wire bonding tool (e.g., the capillary 200) or the bonding wire formed later is not likely to squeeze the first bonding wire 31 when passing proximate to the lower pressing section 311, thereby preventing short circuits and improving product yield.

In some embodiments, the to-be-bonded structure further includes a third bonding pad 23 and a fourth bonding pad 24. The third bonding pad 23 is disposed on the first wire bonding area 101 and adjacent to the first bonding pad 21. The fourth bonding pad 24 is disposed on the second wire bonding area 102 and located on a side of the second bonding pad 22 proximate to the first bonding pad 21. The method of manufacturing the semiconductor device further includes the following steps: a second bonding wire 32 is formed between the third bonding pad 23 and the fourth bonding pad 24 after forming the first bonding wire 31 (i.e., the wire bonding tool moves between the third bonding pad 23 and the fourth bonding pad 24 to form the second bonding wire 32). As shown in FIG. 6, after forming the first bonding wire 31, during forming the second bonding wire 32, the wire bonding tool such as the capillary 200 descends onto the fourth bonding pad 24 during connecting the second bonding wire 32 and the fourth bonding pad 24. Due to difficulty in further reducing a diameter of the capillary 200, and the inability to increase a BH (i.e., a height of a tip of the capillary 200, the diameter at the tip is smaller, while the diameter above the tip is larger) of the capillary 200 without limit, when the first bonding wire 31 adopts a traditional bonding wire structure, the capillary 200 squeezes the first bonding wire 31 to cause the occurrence of the wire collision problem. In the method of manufacturing the semiconductor device provided by the embodiment, the second bonding wire 32 is formed after forming the first bonding wire 31 with the lower pressing section 311, which can avoid the capillary 200 squeezing the first bonding wire 31 during forming the second bonding wire 32, and prevent serious deformation of the first bonding wire 31.

In some embodiments, a length of an orthographic projection of the line connecting the fourth bonding pad 24 to the third bonding pad 23 of the to-be-bonded structure on the plane S′ where the second wire bonding area 102 is located is defined as a third length L3. At the preset position, a difference between the second length L2 and the third length L3 is in a range of −200 μm to 200 μm. As shown in FIG. 6, the first bonding wire 31 extends along the horizontal direction shown in FIG. 6, and the third bonding pad 23 and the fourth bonding pad 24 are arranged along the horizontal direction shown in FIG. 6. That is, the two groups of bonding pads (the first bonding pad 21 and the second bonding pad 22 are one group of bonding pads, and the third bonding pad 23 and the fourth bonding pad 24 are the other group of bonding pads) are arranged in parallel. The second length L2 is the distance (also referred as the horizontal distance) between the lower pressing section 311 and the first bonding pad 21 in the schematic structural diagram from the top-down perspective. The third length L3 is the distance (also referred as the horizontal distance) between the fourth bonding pad 24 and the third bonding pad 23 in the schematic structural diagram from the top-down perspective. The difference between the second length L2 and the third length L3 is in a range of −200 μm to 200 μm, which can be understood that during forming the first bonding wire 31, the wire bonding tool is pressed when the wire bonding tool moves to a position within a range of 200 μm before and after aligning with the fourth bonding pad 24. The lower pressing section 311 is disposed proximate to the fourth bonding pad 24, to thereby avoid the capillary 200 better, and prevent the wire collision.

In some embodiments, a line connecting the first bonding pad 21 to the third bonding pad 23 is defined as a first reference line X1. A length of an orthographic projection of a shortest line connecting the fourth bonding pad 24 to the first reference line X1 on the plane S′ where the second wire bonding area 102 is located is defined as a fourth length L4. At the preset position, a length of an orthographic projection of a shortest line connecting the wire bonding tool to the first reference line X1 on the plane S′ where the second wire bonding area 102 is located is defined as a fifth length L5. A difference between the fifth length L5 and the fourth length L4 is in a range of −200 μm to 200 μm. Specifically, at the preset position, the length (i.e., the fifth length L5) of the orthographic projection of the shortest line connecting the wire bonding tool to the first reference line X1 on the plane S′ where the second wire bonding area 102 is located is the length of the orthographic projection of the shortest line connecting the lower pressing section 311 to the first reference line X1 on the plane S′ where the second wire bonding area 102 is located. According to FIG. 11, the fourth length L4 is a horizontal distance between the fourth bonding pad 24 and the third bonding pad 23 in the schematic structural diagram from the top-down perspective. The fifth length L5 is a horizontal distance between the lower pressing section 311 and the first bonding pad 21 in the schematic structural diagram from the top-down perspective. It can be understood that during forming the first bonding wire 31, the wire bonding tool is pressed when the wire bonding tool moves to a position within a range of 200 μm before and after aligning with the fourth bonding pad 24. The lower pressing section 311 is disposed proximate to the fourth bonding pad 24, to thereby avoid the capillary 200 better, and prevent the wire collision.

In some embodiments, as shown in FIG. 12, an orthographic projection of the first bonding wire 31 on the plane S′ where the second wire bonding area 102 is located is defined as a first projection line PL1. A perpendicular line X3 from the fourth bonding pad 24 to the first projection line PL1 intersects with the first projection line PL1 at a first foot of perpendicular P1. A length of an orthographic projection of a line connecting the first foot of perpendicular P1 to the first bonding pad 21 on the plane S′ where the second wire bonding area 102 is located is defined as a perpendicular distance L7. A difference between the second length L2 and the perpendicular distance L7 is in a range of −100 μm to 100 μm. When the difference between the second length L2 and the perpendicular distance L7 is 0, it can be considered that the position of the lower pressing section 311 is aligned with the position of the fourth bonding pad 24, which can avoid the capillary 200 better. It can be understood that during forming the first bonding wire 31, the wire bonding tool is pressed when the wire bonding tool moves to a position within a range of 200 μm before and after aligning with the fourth bonding pad 24. The lower pressing section 311 is disposed proximate to the fourth bonding pad 24, to thereby avoid the capillary 200 better, and prevent the wire collision.

In some embodiments, the to-be-bonded structure further includes: a fifth bonding pad 25, a sixth bonding pad 26 and a third bonding wire 33, and the third bonding wire 33 connects the fifth bonding pad 25 to the sixth bonding pad 26. The fifth bonding pad 25 is disposed on the first wire bonding area 101 and located on a side of the first bonding pad 21 facing away from the third bonding pad 23, and the fifth bonding pad 25 is adjacent to the first bonding pad 21. The sixth bonding pad 26 is disposed on the second wire bonding area 102 and located on a side of the second bonding pad 22 facing away from the fourth bonding pad 24, and the sixth bonding pad 26 is adjacent to the second bonding pad 22. As shown in FIG. 11, during further forming the first bonding wire 31 and the second bonding wire 32 on the to-be-bonded structure with the third bonding wire 33, the first bonding wire 31 with the lower pressing section 311 is formed at first, and the second bonding wire 32 is formed, so that the problem that the capillary 200 squeezes the first bonding wire 31 during forming the second bonding wire 32, thereby causing the first bonding wire 31 to bend to squeeze the third bonding wire 33, can be avoided when the second bonding wire 32 is formed, and the first bonding wire 31 and the third bonding wire 33 can be prevented from being short-circuited.

In some embodiments, a third bonding pad 23 is further disposed on the first wire bonding area 101, and the third bonding pad 23 is adjacent to the first bonding pad 21. A fourth bonding pad 24 is further disposed on the second wire bonding area 102, and the fourth bonding pad 24 is opposite to the third bonding pad 23. An orthographic projection of the first bonding wire 31 on the plane S′ where the second wire bonding area 102 is located intersects with an orthographic projection of a line connecting the third bonding pad 23 to the fourth bonding pad 24 on the plane S′ where the second wire bonding area 102 is located on an intersection X21. The method of manufacturing the semiconductor device further includes the following steps: a second bonding wire 32 is formed between the third bonding pad 23 and the fourth bonding pad 24 after forming the first bonding wire 31 (i.e., the wire bonding tool moves between the third bonding pad 23 and the fourth bonding pad 24 to form the second bonding wire 32). As shown in FIG. 14, the second bonding wire 32 forms an intersecting wire bonding with the first bonding wire 31 after forming the second bonding wire 32. Therefore, the first bonding wire 31 with the lower pressing section 311 is formed before forming the second bonding wire 32, so that during forming the second bonding wire 32, when the capillary 200 or the second bonding wire 32 passes over the first bonding wire 31, it is not easy to collide with the first bonding wire 31 after forming the second bonding wire 32.

Specifically, as shown in FIG. 14, a length of an orthographic projection of the line connecting the intersection X21 to the first bonding pad 21 on the plane S′ where the second wire bonding area 102 is located is defined as a sixth length L6. A difference between the second length L2 and the sixth length L6 is in a range of −200 μm to 200 μm. It can be understood that during forming the first bonding wire 31, the wire bonding tool is pressed within 200 μm before and after the position corresponding to the intersection X21 to form the lower pressing section 311, which can control the first bonding wire 31 better to form a low position on a corresponding area of the intersection X21, to thereby prevent the occurrence of the wire collision.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor device, comprising:
at least one carrier;
a first wire bonding area, disposed on the at least one carrier; wherein a first bonding pad is disposed on the first wire bonding area;
a second wire bonding area, disposed on the at least one carrier; wherein a second bonding pad is disposed on the second wire bonding area; and
at least one bonding wire, comprising a first bonding wire that connects the first bonding pad to the second bonding pad;
wherein the first bonding wire comprises:
a lower pressing section; and
a first line segment connecting the lower pressing section to the first bonding pad;
wherein a distance between the lower pressing section and a plane where the second wire bonding area is located is defined as a first height, and the first height is smaller than 400 μm; and a length of an orthographic projection of the first bonding wire on the plane where the second wire bonding area is located is defined as a first length, while a length of an orthographic projection of the first line segment on the plane where the second wire bonding area is defined as a second length, and the second length is 20% to 80% of the first length.

2. The semiconductor device according to claim 1, wherein a third bonding pad is disposed on the first wire bonding area, and the third bonding pad is adjacent to the first bonding pad; a fourth bonding pad is disposed on the second wire bonding area, and the fourth bonding pad is opposite to the third bonding pad; the fourth bonding pad is located on a side of the second bonding pad proximate to the first bonding pad; and the third bonding pad is connected to the fourth bonding pad by a second bonding wire.

3. The semiconductor device according to claim 2, wherein an orthographic projection of a line connecting the third bonding pad to the fourth bonding pad on the plane where the second wire bonding area is located has a third length, and a difference between the second length and the third length is in a range of −200 μm to 200 μm.

4. The semiconductor device according to claim 2, wherein a line connecting the first bonding pad to the third bonding pad is defined as a first reference line, an orthographic projection of a shortest line connecting the fourth bonding pad to the first reference line on the plane where the second wire bonding area is located has a fourth length, and an orthographic projection of a shortest line connecting the lower pressing section to the first reference line on the plane where the second wire bonding area is located has a fifth length, and a difference between the fifth length and the fourth length is in a range of −200 μm to 200 μm.

5. The semiconductor device according to claim 2, wherein an orthographic projection of the first bonding wire on the plane where the second wire bonding area is located is defined as a first projection line; and a perpendicular line from the fourth bonding pad to the first projection line intersects with the first projection line at a first foot of perpendicular, a length of an orthographic projection of a line connecting the first foot of perpendicular to the first bonding pad on the plane where the second wire bonding area is located is defined as a perpendicular distance, and a difference between the second length and the perpendicular distance is in a range of −100 μm to 100 μm.

6. The semiconductor device according to claim 1, wherein a third bonding pad is disposed on the first wire bonding area, and the third bonding pad is adjacent to the first bonding pad; a fourth bonding pad is disposed on the second wire bonding area, and the fourth bonding pad is opposite to the third bonding pad, the third bonding pad is connected to the fourth bonding pad by a second bonding wire; and an orthographic projection of the first bonding wire on the plane where the second wire bonding area is located intersects with an orthographic projection of a line connecting the third bonding pad to the fourth bonding pad on the plane where the second wire bonding area is located on an intersection.

7. The semiconductor device according to claim 6, wherein an orthographic projection of a line connecting the intersection to the first bonding pad on the plane where the second wire bonding area is located has a sixth length, and a difference between the second length and the sixth length is in a range of −200 μm to 200 μm.

8. The semiconductor device according to claim 6, wherein the at least one bonding wire further comprises the second bonding wire connected between the third bonding pad and the fourth bonding pad, and a minimum distance between the first bonding wire and the second bonding wire is greater than or equal to one time of a diameter of the at least one bonding wire.

9. The semiconductor device according to claim 1, wherein the first height is greater than or equal to one time of the diameter of the at least one bonding wire.

10. The semiconductor device according to claim 1, wherein the first wire bonding area and the second wire bonding area are located on a surface of the at least one carrier and are located on different areas of the at least one carrier.

11. The semiconductor device according to claim 1, further comprising:
a first carrier; wherein the first wire bonding area is located on the first carrier; and
a second carrier; wherein the second wire bonding area is located on the second carrier.

12. The semiconductor device according to claim 11, wherein the first carrier is a chip, the second carrier is a substrate, the first carrier is disposed on the second carrier, and the first carrier is electrically connected to the second carrier by the first bonding wire.

13. The semiconductor device according to claim 8, wherein the diameter of the at least one bonding wire is in a range of 15 μm to 60 μm.

14. The semiconductor device according to claim 1, wherein the first bonding wire further includes a second line segment connecting the lower pressing section to the second bonding pad, a highest distance between the second line segment and the plane where the second wire bonding area is located is defined as a second height, and the second height is greater than the first height.

15. The semiconductor device according to claim 14, wherein at least one point on the second line segment is higher than the lower pressing section.

16. A method of manufacturing a semiconductor device, comprises:
providing at least one carrier that includes a first wire bonding area and a second wire bonding area;
disposing a first bonding pad on the first wire bonding area;
disposing a second bonding pad on the second wire bonding area, wherein a length of an orthographic projection of a line connecting the first bonding pad to the second bonding pad on a plane where the second wire bonding area is located is defined as a first length; and
forming a first bonding wire between the first bonding pad and the second bonding pad, and creating a lower pressing section on the first bonding wire; and
wherein a distance between the lower pressing section and the plane where the second wire bonding area is located is defined as a first height, and the first height is smaller than 400 μm; and a length of an orthographic projection of a line connecting the lower pressing section to the first bonding pad on the plane where the second wire bonding area is located is defined as a second length, and the second length is 20% to 80% of the first length.

17. The method of manufacturing the semiconductor device according to claim 16, further comprising:
driving a bonding wire to move between the first bonding pad and the second bonding pad by using a wire bonding tool to form the first bonding wire, and when the wire bonding tool moves to a preset position, pressing the wire bonding tool facing towards a direction proximate to the second wire bonding area to create the lower pressing section on the first bonding wire, wherein the first height is smaller than a height of a tip of the wire bonding tool.

18. The method of manufacturing the semiconductor device according to claim 16, further comprising:
disposing a third bonding pad on the first wire bonding area and adjacent to the first bonding pad;
disposing a fourth bonding pad on the second wire bonding area and located on a side of the second bonding pad proximate to the first bonding pad; and
forming a second bonding wire between the third bonding pad and the fourth bonding pad after forming the first bonding wire.

19. The method of manufacturing the semiconductor device according to claim 18, further comprising:
a fifth bonding pad, disposed on the first wire bonding area and located on a side of the first bonding pad facing away from the third bonding pad; wherein the fifth bonding pad is adjacent to the first bonding pad;
a sixth bonding pad, disposed on the second wire bonding area and located on a side of the second bonding pad facing away from the fourth bonding pad; wherein the sixth bonding pad is adjacent to the second bonding pad; and
a third bonding wire, connected between the fifth bonding pad and the sixth bonding pad.

20. The method of manufacturing the semiconductor device according to claim 16, further comprising:
disposing a third bonding pad on the first wire bonding area and adjacent to the first bonding pad;
disposing a fourth bonding pad on the second wire bonding area and opposite to the third bonding pad, wherein an orthographic projection of the first bonding wire on the plane where the second wire bonding area is located intersects with an orthographic projection of a line connecting the third bonding pad to the fourth bonding pad on the plane where the second wire bonding area is located on an intersection; and
forming a second bonding wire between the third bonding pad and the fourth bonding pad after forming the first bonding wire.
